(19) United States
(12) Patent Application Publication
(10) Pub. No.: US 2016/0013020 A1
(43) Pub. Date: Jan. 14, 2016

(54) SYSTEMS AND METHODS FOR PRODUCING ENERGETIC NEUTRALS

(71) Applicant: Lam Research Corporation, Fremont, CA (US)

(72) Inventors: Kaihan Ashtiani, Cupertino, CA (US); Canfeng Lai, Fremont, CA (US); Liang Meng, Milpitas, CA (US)

(21) Appl. No.: 14/740,469

(22) Filed: Jun. 16, 2015

Related U.S. Application Data
(60) Provisional application No. 62/024,080, filed on Jul. 14, 2014.

(51) Int. Cl. H01J 37/32; C23C 16/458; C23C 16/52; C23C 16/46; C23C 16/503; C23C 16/455; C23C 16/50

(52) U.S. Cl. CPC H01J 37/3244; C23C 16/45544; C23C 16/458; C23C 16/50; C23C 16/46; C23C 16/45565; C23C 16/503; C23C 16/52; H01J 37/32082; H01J 37/32449

(57) ABSTRACT

Systems and methods for producing energetic neutrals include a remote plasma generator configured to generate plasma in a plasma region. An ion extractor is configured to extract high energy ions from the plasma. A substrate support is arranged in a processing chamber and is configured to support a substrate. A neutral extractor and gas dispersion device is arranged between the plasma region and the substrate support. The neutral extractor and gas dispersion device is configured to extract energetic neutrals from the high energy ions, to supply the energetic neutrals to the substrate and to disperse precursor gas into the processing chamber.

### CROSS-REFERENCE TO RELATED APPLICATIONS

This application claims the benefit of U.S. Provisional Application No. 62/024,080, filed on Jul. 14, 2014. The entire disclosure of the application referenced above is incorporated herein by reference.

### FIELD

The present disclosure relates to substrate processing systems, and more particularly to systems and methods for producing energetic neutrals for substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

The semiconductor industry uses a remote plasma source to generate radicals for nanotechnology applications. The remote plasma source can include an inductively-coupled plasma (ICP) generator, a transformer-coupled plasma (TCP) generator, a capacitively-coupled plasma (CCP) generator and/or a microwave plasma generator.

In some applications, a showerhead or a plasma grid is used to neutralize the plasma and to allow only neutral particles to pass. The radicals generated using these approaches typically have low energy (−0.01 eV). Therefore, the radicals have limited activation energy for film densification for atomic layer deposition (ALD) or atomic layer etching (ALE) processes.

When in-situ plasma densification methods are used, the ion energy is often too high. High ion energy may cause damage to devices in the substrate. The directionality of the ions also reduces the efficiency of side wall film densification. In terms of energetic neutral generation, existing approaches can process only limited substrate areas and are generally not available for larger areas such as 300 mm or 450 mm diameter wafers.

### SUMMARY

A system for producing energetic neutrals includes a remote plasma generator configured to generate plasma in a plasma region. An ion extractor is configured to extract high energy ions from the plasma. A substrate support is arranged in a processing chamber and is configured to support a substrate. A neutral extractor and gas dispersion device is arranged between the plasma region and the substrate support. The neutral extractor and gas dispersion device is configured to extract energetic neutrals from the high energy ions, to supply the energetic neutrals to the substrate and to disperse precursor gas into the processing chamber.

In other features, a heater is configured to heat the substrate to a predetermined temperature. The neutral extractor and gas dispersion device includes a showerhead. The showerhead defines a first plenum in the showerhead for receiving the precursor gas. The showerhead includes a first plurality of holes in a substrate-facing surface thereof that are in fluid communication with the first plenum.

In other features, a distance between the showerhead and the substrate is selected to be within a lifetime of the energetic neutrals. The showerhead further includes a second plurality of holes that extend from an ion extractor-facing surface of the showerhead to the substrate-facing surface of the showerhead.

In other features, the showerhead is made of ceramic. An electrode is arranged adjacent to the ion extractor-facing surface of the showerhead. The electrode is biased by a ground reference potential. The electrode includes a third plurality of holes that align with the second plurality of holes.

In other features, the plasma generator includes an electrode arranged spaced from the neutral extractor and gas dispersion device. The plasma region is located between the electrode and the neutral extractor and gas dispersion device. A gas delivery system is configured to supply plasma gas to the plasma region. An RF power generator selectively outputs RF power to the electrode to generate plasma.

In other features, the ion extractor includes a DC power generator that selectively outputs DC voltage to the electrode. The DC voltage is a constant, positive DC voltage or a pulsed, positive DC voltage. The showerhead is configured to deliver precursor gas to the substrate separately from the energetic neutrals. In other features, the showerhead is made of metal. The showerhead includes a dielectric layer arranged on at least one surface thereof.

In other features, the energetic neutrals have energy in a range from 1 eV to 100 eV. The energetic neutrals have energy in a range from 5 eV to 10 eV.

In other features, a controller is configured to control a gas delivery system to supply plasma gas to the plasma region and the precursor gas, control an RF generator to strike the plasma in the plasma region, and control a DC power generator to output DC voltage to the ion extractor.

A method for producing energetic neutrals includes remotely generating plasma in a plasma region; extracting high energy ions from the plasma; extracting energetic neutrals from the high energy ions; supplying the energetic neutrals to a substrate in a processing chamber; and supplying precursor gas to the processing chamber.

In other features, the method includes heating the substrate to a predetermined temperature. The method includes extracting the energetic neutrals and supplying the precursor gas using a showerhead. A distance between the showerhead and the substrate is selected to be within a lifetime of the energetic neutrals.

In other features, the method includes defining a first plenum in the showerhead for receiving the precursor gas. A first plurality of holes in the showerhead communicate with the first plenum and are arranged on a substrate-facing surface thereof. The showerhead further includes a second plurality of holes that pass from an ion extractor-facing surface of the showerhead to the substrate-facing surface of the showerhead. In other features, the showerhead is made of ceramic. The method includes arranging an electrode adjacent to the ion extractor-facing surface of the showerhead.

In other features, remotely generating the plasma further includes: providing an electrode in the plasma region; supplying plasma gas to the plasma region; and selectively outputting RF power to the electrode to generate plasma.

In other features, the method includes selectively outputting DC voltage to the electrode to extract the energetic neutrals. The DC voltage is a constant, positive DC voltage or a pulsed, positive DC voltage.

In other features, the method includes delivering the precursor gas to the processing chamber separately from the energetic neutrals. The showerhead is made of metal. The showerhead includes a dielectric layer arranged on at least one surface thereof.

In other features, the energetic neutrals have energy in a range from 1 eV to 100 eV. The energetic neutrals have energy in a range from 5 eV to 10 eV.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example of a substrate processing system according to the present disclosure;

FIG. 2A is a functional block diagram of another example of a substrate processing system according to the present disclosure;

FIG. 2B is a cross-sectional view of the showerhead of FIG. 2A; and

FIG. 3 illustrates an example of a method for processing a substrate according to the present disclosure.

In the drawings, reference numbers may be reused to identify similar and/or identical elements.

### DETAILED DESCRIPTION

Systems and methods according to the present disclosure enable energetic neutral production over a relatively large surface area. The systems and methods can be utilized in processes such as atomic layer deposition (ALD), atomic layer etching (ALE) or nanotechnology processes. Systems and methods according to the present disclosure reduce problems associated with prior approaches such as production of only low energy neutrals (such as those less than 0.5 eV), or a neutral beam for very small surface areas (such as those less having diameters that are less than 100 mm).

The systems and methods according to the present disclosure provide high density energetic neutrals (radicals) to improve sidewall densification efficiency for ALD/ALE. Due to the isotropic nature of the neutrals, the deposition (and etching) may be more conforming for small nanometer scale features with high aspect ratio trenches, which can be a desirable requirement for some substrate processes. The systems and methods according to the present disclosure also provide a uniform source of energetic neutrals over a large area, such as substrates having diameters of 300 mm, 450 mm or larger.

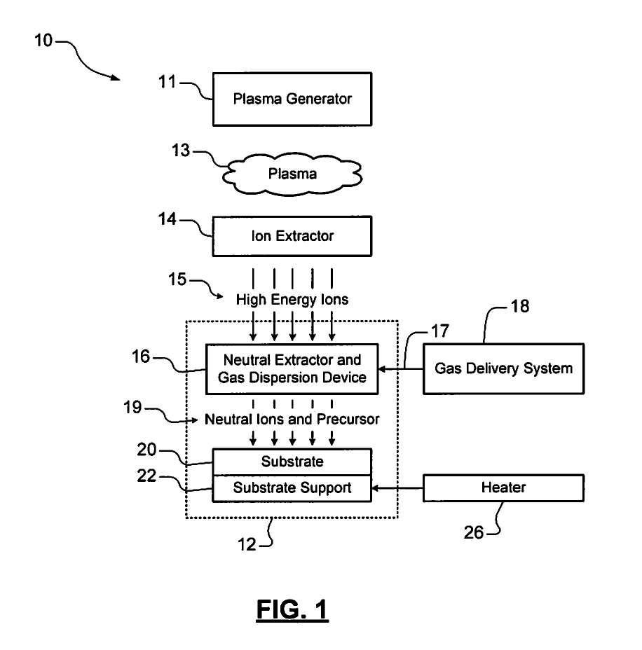

Referring now to FIG. 1, an example of a substrate processing system 10 is shown. A plasma generator 11 is located upstream from a processing chamber 12. In some examples, the plasma generator 11 generates plasma 13 to create high density ions. The plasma generator 11 may include a capacitively-coupled plasma (CCP) generator, an inductively-coupled plasma (ICP) generator, a microwave plasma generator or other suitable plasma generator 11.

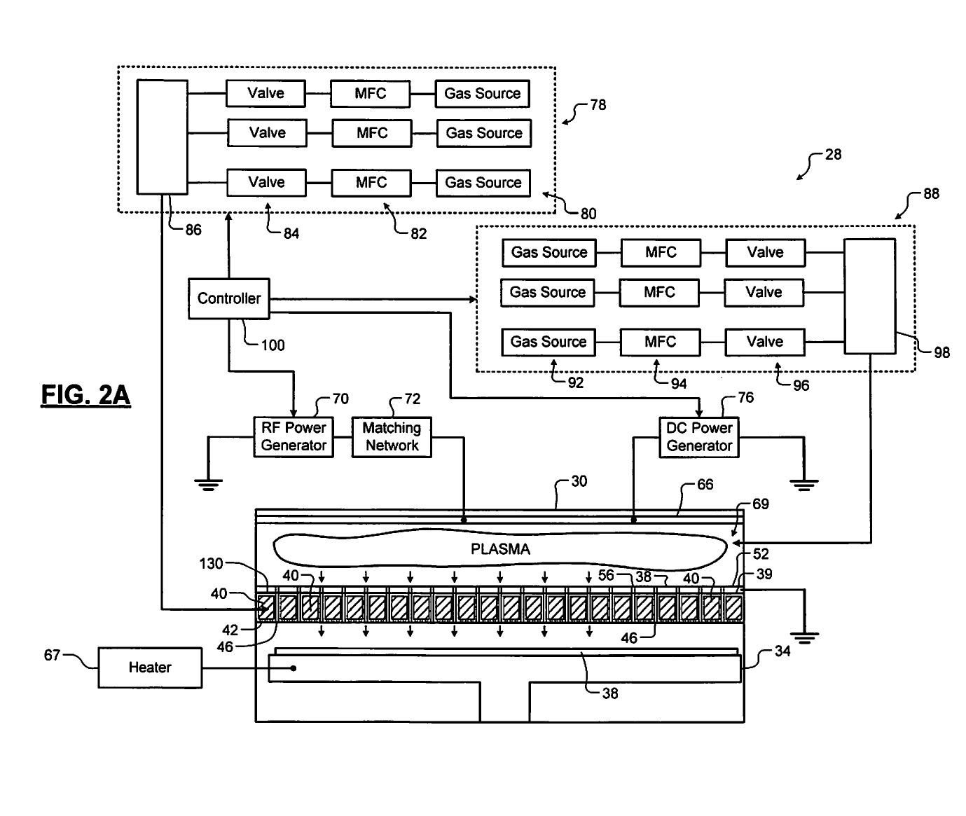

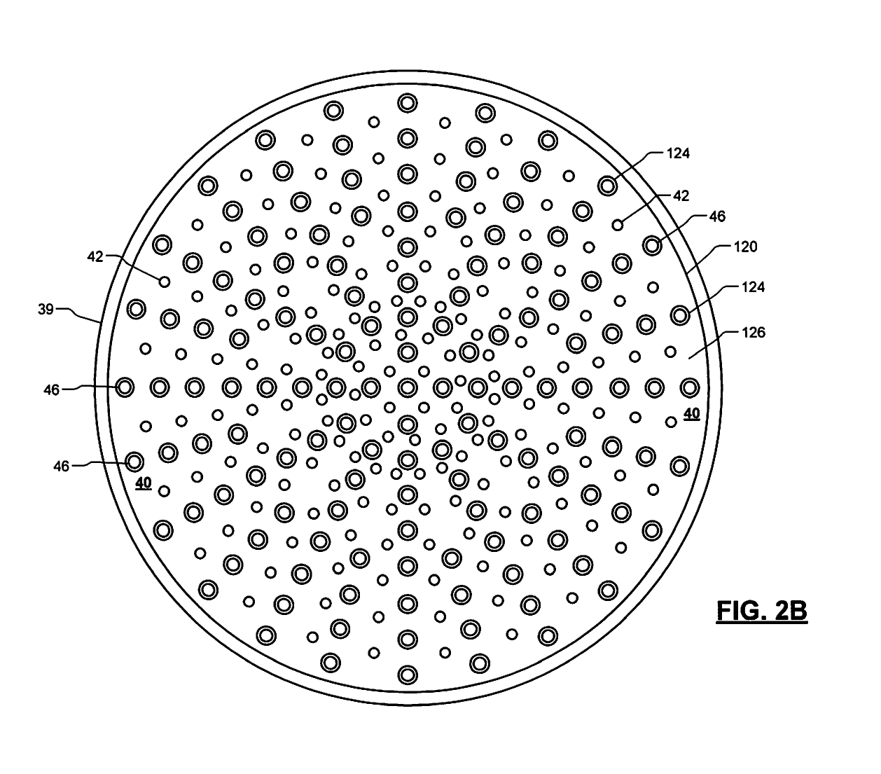

An ion extractor 14 extracts high energy ions 15 from the plasma 13. For example only for CCP generator configurations, the ion extractor 14 may include an electrode (see e.g., FIG. 2A) that is biased by RF power and a high positive DC bias (e.g. up to the kilovolts range). The high positive DC bias may be a constant or pulsed DC voltage.

A neutral extractor and gas dispersion device 16 receives the high energy ions 15 from the ion extractor 14 and one or more gas precursors 17 from a gas delivery system 18. The neutral extractor and gas dispersion device 16 extracts high energy neutrals 19 from the high energy ions 15. The neutral extractor and gas dispersion device 16 distributes the high energy neutrals 19 and the precursor gas 17 across an exposed surface of a substrate 20 arranged on a substrate support 22. For example, the substrate support 22 may include a pedestal, an electrostatic chuck, a chuck, a platen or other suitable substrate support.

The constant DC voltage bias applied by the ion extractor 14 to the electrode raises the plasma potential and forms a large ion sheath to accelerate ions towards the neutral extractor and gas dispersion device 16 while electrons are repelled away from the neutral extractor and gas dispersion device 16. A surface of the neutral extractor and gas dispersion device 16 that is exposed to the accelerated ions may include a material that is selected to endure possible ion sputtering.

The constant DC bias applied by the ion extractor 14 can be replaced with a pulsed DC voltage bias. The pulsed DC voltage bias may allow higher peak DC voltage to be applied and thus higher ion energies. In some examples, the average DC current drawn can be maintained at a reasonably low value to avoid extinguishing the RF plasma.

A temperature of the substrate support 22 may be controlled using the heater 26 to provide reaction enhancement. The substrate support 22 is arranged immediately below the neutral extractor and gas dispersion device 16 within a lifetime of the neutrals depending on pressure in the processing chamber 12.

Referring now to FIG. 2A, an example of a substrate processing system 28 is shown and includes a processing chamber 30. A substrate support 34 is arranged in the processing chamber 30 to provide support for a substrate 38 such as a semiconductor wafer. A showerhead 39 defines a first plenum 40 that receives a gas mixture including one or more precursors. The first plenum 40 includes a plurality of holes 42 in a lower surface thereof to uniformly disperse the gas mixture across an upwardly facing surface of the substrate 38. The showerhead 39 further includes holes 46 that pass from a first surface (such as a top wall) of the showerhead 39 to a second surface (such as a bottom wall) of the showerhead 39 that is opposite to the first surface. The holes 46 provide a fluid communication path from the upper plasma region to the downstream region but are not in fluid communication with the first plenum 40 or the holes 42.

In some examples, an electrode 52 is provided and is arranged adjacent to the first surface of the showerhead 39. If provided, the electrode 52 may be made of a conducting material such as metal and may be grounded. The electrode 52 includes a plurality of holes 56 that align with the holes 46 of the showerhead 39.

A heater 67 may be provided to control a temperature of the substrate support 34 and the substrate 38. An electrode 66 may be arranged in a spaced relationship relative to the showerhead 39 and the electrode 52 to define an upstream plasma region 69. The electrode 66 may be made of a conducting material such as metal.

In this example, capacitively coupled plasma (CCP) is generated by applying a radio frequency (RF) power supplied by RF power generator 70 through a matching network 72 to the electrode 66. In addition, a constant or pulsed DC voltage is supplied by a DC power generator 76 to the electrode 66.

The first gas mixture provided to the showerhead 39 may be supplied by a gas delivery system 78 that includes one or more gas sources 80, one or more mass flow controllers (MFC) 82, one or more valves 84 and one or more manifolds 86. A second gas mixture may be supplied by a gas delivery system 88 that includes one or more gas sources 92, one or more mass flow controllers (MFC) 94, one or more valves 96, and one or more manifolds 98 to the upstream plasma region.

A controller 100 may be provided to control the process. For example, the controller 100 controls the valves and MFCs associated with the gas delivery systems 78 and 88. In addition, the controller 100 may control generation of the RF power by the RF power generator 70 and the constant or pulsed DC voltage from the DC power generator 76. The controller 100 may also control the heater 67. In addition, the controller 100 may monitor one or more process parameters in the upstream plasma region 69 or the region downstream from the showerhead 39 using temperature sensors, pressure sensors or other types of sensors.

In operation, the gas delivery system 88 supplies the second gas mixture to the upstream plasma region 69 located between the electrode 66 and the showerhead 39. The RF power generator 70 supplies the RF power to the electrode 66. Plasma is struck in the upstream plasma region 69. The DC power generator 76 may supply a constant or pulsed DC voltage to the electrode 66 to perform ion extraction.

The high energy ions may partially neutralize on a surface of the holes 46 of the showerhead 39 to become fast neutrals and charge exchange may occur when the ions pass through a targeted gaseous medium. The species of the targeted gaseous medium is selected to optimize the charge exchange efficiency. Charge exchange can happen within the holes 46 of the showerhead 39 and after the showerhead 39.

The number of holes 46 in the showerhead 39 and the sizes of the holes are optimized to have large transparency for neutrals/radicals and low recombination loss. Since energetic neutrals are extracted at higher velocities, their collision cross sections are typically lower; thus less recombination and more extraction into the process region may occur. The energetic neutrals are delivered with high energy to the substrate.

In some examples, the showerhead 39 is a dual-zone (plenum) showerhead with the capability of delivering the precursor to the processing zone independently from the high energy neutrals. The neutrals and radicals are filtered through the holes 46. The holes 42 deliver the precursor to the downstream processing zone. If the showerhead 39 is made of a conducting material such as metal, the showerhead 39 may be grounded and the electrode 52 may be omitted. If the showerhead is made of a non-conducting material such as ceramic, the electrode 52 may be provided and grounded.

For ICP and microwave plasma, a DC-biased electrode can also be incorporated to raise the plasma potential in a similar manner.

If the showerhead is made of metal, the surface of the showerhead 39 facing the upstream plasma region can be partially covered with a layer of dielectric material having openings aligned with the holes 46. As a result, the essential electrode surface area is reduced. This approach may induce a higher RF sheath voltage at the showerhead 39 to facilitate ion acceleration in addition to the DC bias effect. If the showerhead is made of ceramic, the electrode 52 can be designed to achieve the same effect.

Referring now to FIG. 2B, the showerhead 39 includes circumferential sidewalls 120 and a plurality of interior walls 124. The circumferential sidewalls 120 and the plurality of interior walls 124 extend from a top wall 130 or surface (FIG. 2A) of the showerhead 39 facing the upstream plasma region to a bottom wall or surface 126 of the showerhead 39 facing the substrate 38. The holes 46 pass through the top wall 130, the interior walls 124 and the bottom wall 126. The bottom wall surface 126 of the showerhead 39 includes the plurality of holes 42 to allow gas flow from the plenum 40 through the bottom wall 126 to the substrate 38.

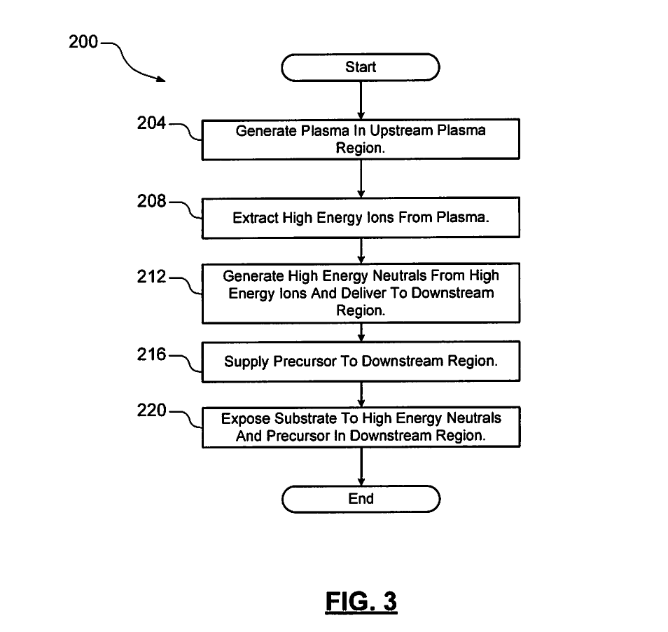

Referring now to FIG. 3, an example of a method 200 for processing a substrate is shown. At 204, plasma is generated in an upstream plasma region. At 208, high energy ions are extracted from the plasma. At 212, high energy neutrals are generated from the high energy ions and are delivered to a downstream region. At 216, one or more precursors are supplied to the downstream region. At 220, a substrate is exposed to the high energy neutrals and the one or more precursors.

In conventional system, a remote plasma source was used with a grounded plenum and had low energy neutrals (˜0.01 eV). In contrast, the systems and methods described herein use the plasma source, the ion extractor, the dual plenum and the neutral extractor. The systems and methods described herein provide energetic neutrals (from ˜1 eV to 100 eV) with high activation energy and without charge damage. The energetic neutrals may be provided over a large area to support uniform processes. For example, substrate areas such as those with diameters of 300 mm, 450 mm and larger can be accommodated. The systems and methods are suitable for high pressure (˜Torr) and is applicable for a wide range of processes.

For example only, neutral energy on the order of 5-10 eV may be appropriate since much lower energies may not drive the desired reactions and much higher energies may cause damage. The pressure should be high enough to produce an isotropic spatial distribution of neutrals at the wafer (i.e. not highly directional) but not so high that the neutral flux at the wafer is unacceptably low due to scattering with the background gas.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A system for producing energetic neutrals, comprising:
a remote plasma generator configured to generate plasma in a plasma region;
an ion extractor configured to extract high energy ions from the plasma;
a processing chamber;
a substrate support arranged in the processing chamber and configured to support a substrate; and
a neutral extractor and gas dispersion device arranged between the plasma region and the substrate support, wherein the neutral extractor and gas dispersion device is configured to extract energetic neutrals from the high energy ions, to supply the energetic neutrals to the substrate and to disperse precursor gas into the processing chamber.

2. The system of claim 1, further comprising a heater configured to heat the substrate to a predetermined temperature.

3. The system of claim 1, the neutral extractor and gas dispersion device includes a showerhead.

4. The system of claim 3, wherein a distance between the showerhead and the substrate is selected to be within a lifetime of the energetic neutrals.

5. The system of claim 3, wherein:
the showerhead defines a first plenum in the showerhead for receiving the precursor gas; and
the showerhead includes a first plurality of holes in a substrate-facing surface thereof that are in fluid communication with the first plenum.

6. The system of claim 5, wherein the showerhead further includes a second plurality of holes that extend from an ion extractor-facing surface of the showerhead to the substrate-facing surface of the showerhead.

7. The system of claim 6, wherein the showerhead is made of ceramic and further comprising an electrode arranged adjacent to the ion extractor-facing surface of the showerhead.

8. The system of claim 7, wherein the electrode is biased by a ground reference potential.

9. The system of claim 7, wherein the electrode includes a third plurality of holes that align with the second plurality of holes.

10. The system of claim 1, wherein the remote plasma generator includes:
an electrode arranged spaced from the neutral extractor and gas dispersion device, wherein the plasma region is located between the electrode and the neutral extractor and gas dispersion device;
a gas delivery system configured to supply plasma gas to the plasma region; and
an RF power generator that selectively outputs RF power to the electrode to generate plasma.

11. The system of claim 10, wherein the ion extractor includes a DC power generator that selectively outputs DC voltage to the electrode.

12. The system of claim 11, wherein the DC voltage is a constant, positive DC voltage.

13. The system of claim 11, wherein the DC voltage is a pulsed, positive DC voltage.

14. The system of claim 3, wherein the showerhead is configured to deliver precursor gas to the substrate separately from the energetic neutrals.

15. The system of claim 3, wherein the showerhead is made of metal.

16. The system of claim 15, wherein the showerhead includes a dielectric layer arranged on at least one surface thereof.

17. The system of claim 1, wherein the energetic neutrals have energy in a range from 1 eV to 100 eV.

18. The system of claim 1, wherein the energetic neutrals have energy in a range from 5 eV to 10 eV.

19. The system of claim 1, further comprising a controller configured to:
control a gas delivery system to supply plasma gas to the plasma region and the precursor gas;
control an RF generator to strike the plasma in the plasma region; and
control a DC power generator to output DC voltage to the ion extractor.

20. A method for producing energetic neutrals, comprising:
remotely generating plasma in a plasma region;
extracting high energy ions from the plasma;
extracting energetic neutrals from the high energy ions;
supplying the energetic neutrals to a substrate in a processing chamber; and
supplying precursor gas to the processing chamber.

21. The method of claim 20, further comprising heating the substrate to a predetermined temperature.

22. The method of claim 20, further comprising extracting the energetic neutrals and supplying the precursor gas using a showerhead.

23. The method of claim 22, wherein a distance between the showerhead and the substrate is selected to be within a lifetime of the energetic neutrals.

24. The method of claim 22, further comprising defining a first plenum in the showerhead for receiving the precursor gas and a first plurality of holes that communicate with the first plenum, wherein the first plurality of holes are arranged on a substrate-facing surface thereof.

25. The method of claim 24, wherein the showerhead further includes a second plurality of holes that extend from an ion extractor-facing surface of the showerhead to the substrate-facing surface of the showerhead.

26. The method of claim 25, wherein the showerhead is made of ceramic and further comprising arranging an electrode adjacent to the ion extractor-facing surface of the showerhead.

27. The method of claim 21, wherein remotely generating the plasma further includes:
providing an electrode in the plasma region;
supplying plasma gas to the plasma region; and
selectively outputting RF power to the electrode to generate plasma.

28. The method of claim 27, further comprising selectively outputting DC voltage to the electrode to extract the energetic neutrals.

29. The method of claim 28, wherein the DC voltage is a constant, positive DC voltage.

30. The method of claim 28, wherein the DC voltage is a pulsed, positive DC voltage.

31. The method of claim 21, further comprising delivering the precursor gas to the processing chamber separately from the energetic neutrals.

32. The method of claim 22, wherein the showerhead is made of metal.

33. The method of claim 32, wherein the showerhead includes a dielectric layer arranged on at least one surface thereof.

34. The method of claim 21, wherein the energetic neutrals have energy in a range from 1 eV to 100 eV.

35. The method of claim 21, wherein the energetic neutrals have energy in a range from 5 eV to 10 eV.
